(19) United States
(12) Patent Application Publication
(10) Pub. No.: US 2026/0322065 A1
(43) Pub. Date: Oct. 15, 2026

(54) LASER DEVICE AND ELECTRONIC DEVICE MANUFACTURING METHOD

(71) Applicant: Gigaphoton Inc., Tochigi (JP)

(72) Inventors: Momoko KUJIRA, Tochigi (JP); Kazuhiro SUZUKI, Tochigi (JP)

(73) Assignee: Gigaphoton Inc., Tochigi (JP)

(21) Appl. No.: 19/467,891

(22) Filed: Feb. 3, 2026

(30) Foreign Application Priority Data
Mar. 10, 2025 (JP) 2025-037335

(51) Int. Cl. H01S 3/13; G03F 7/00

(52) U.S. Cl. CPC H01S 3/1305; G03F 7/70025; G03F 7/70041

(57) ABSTRACT

A laser device includes a laser oscillator configured to perform laser oscillation, a controller configured to control the laser oscillator, an interface connected between an external apparatus and the controller, and a communication monitoring device connected to the interface. Here, the communication monitoring device is configured to detect a first signal transmitted and received via the interface and a second signal transmitted and received via the interface subsequent to the first signal, measure a time from detection of the first signal to detection of the second signal, and notify the controller of information regarding the time. One of the controller and the communication monitoring device determines whether or not the time is less than a threshold.

### CROSS-REFERENCE TO RELATED APPLICATIONS

The present application claims the benefit of Japanese Patent Application No. 2025-037335, filed on Mar. 10, 2025, the entire contents of which are hereby incorporated by reference.

### BACKGROUND

### 1. Technical Field

The present disclosure relates to a laser device and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

Since excimer laser light output from each of the KrF excimer laser device and the ArF excimer laser device has a pulse width of several 10 ns and a wavelength is short as about 248 nm or about 193 nm, excimer laser light is sometimes used for direct processing of a polymer material, a glass material, or the like. Chemical bonds in polymeric materials can be broken by excimer laser light having a photon energy higher than the bond energy. Therefore, it is known that non-heating processing of polymeric materials is possible with excimer laser light, and that the processing shape is beautiful. Further, it is known that, since glass, ceramics, and the like have high absorptance with respect to excimer laser light, even a material that is difficult to be processed with visible and infrared laser light can be processed with excimer laser light.

### LIST OF DOCUMENTS

### Patent Documents

Patent Document 1: US Patent Application Publication No. 2024/0394446

Patent Document 2: US Patent Application Publication No. 2018/0196347

### SUMMARY

A laser device according to an aspect of the present disclosure includes a laser oscillator configured to perform laser oscillation, a controller configured to control the laser oscillator, an interface connected between an external apparatus and the controller, and a communication monitoring device connected to the interface. Here, the communication monitoring device is configured to detect a first signal transmitted and received via the interface and a second signal transmitted and received via the interface subsequent to the first signal, measure a time from detection of the first signal to detection of the second signal, and notify the controller of information regarding the time. One of the controller and the communication monitoring device determines whether or not the time is less than a threshold.

An electronic device manufacturing method according to an aspect of the present disclosure includes generating pulse laser light using a laser device, outputting the pulse laser light to an exposure apparatus, and exposing a photosensitive substrate to the pulse laser light in the exposure apparatus to manufacture an electronic device. Here, the laser device includes a laser oscillator configured to perform laser oscillation, a controller configured to control the laser oscillator, an interface connected between the exposure apparatus and the controller, and a communication monitoring device connected to the interface. The communication monitoring device is configured to detect a first signal transmitted and received via the interface and a second signal transmitted and received via the interface subsequent to the first signal, measure a time from detection of the first signal to detection of the second signal, and notify the controller of information regarding the time. One of the controller and the communication monitoring device determines whether or not the time is less than a threshold.

### BRIEF DESCRIPTION OF THE DRAWINGS

Embodiments of the present disclosure will be described below merely as examples with reference to the accompanying drawings.

FIG. 1 shows the configuration of an exposure system of a comparative example.

FIG. 2 shows a configuration example of a system for checking a communication state between a laser device and an exposure apparatus in the comparative example.

FIG. 3 shows the configuration of the laser device of a first embodiment.

FIG. 4 shows an example of signals detected by a measurement determination circuit in the first embodiment.

FIG. 5 is a flowchart showing processing of a communication monitoring device in the first embodiment.

FIG. 6 shows the configuration of the laser device of a second embodiment.

FIG. 7 shows an example of signals transmitted and received by a polling circuit in the second embodiment.

FIG. 8 is a flowchart showing processing of the communication monitoring device in the second embodiment.

FIG. 9 is a flowchart showing processing of the controller when S23 and S24 are omitted in the second embodiment.

FIG. 10 shows the configuration of an exposure apparatus.

### DESCRIPTION OF EMBODIMENTS

<Contents>
1. Comparative example
   1.1 Exposure system
   1.2 Laser device 1
      1.2.1 Configuration
      1.2.2 Operation
   1.3 Problem of comparative example
2. Laser device 1 including communication monitoring device 20 connected to interface IF
   2.1 Configuration
   2.2 Operation
   2.3 Effect
3. Laser device 1 including communication monitoring device 20 that performs polling
   3.1 Configuration
   3.2 Operation
   3.3 Effect
4. Others
   4.1 Processor
   4.2 Electronic device manufacturing method
4.3 Supplement

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Comparative Example

### 1.1 Exposure System

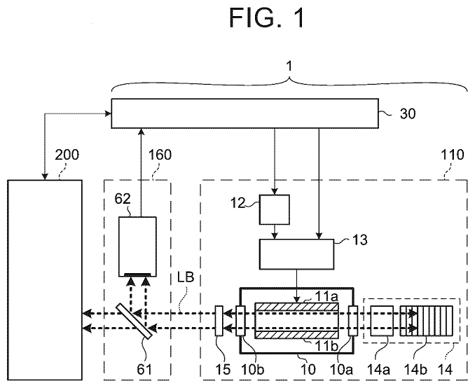

FIG. 1 shows the configuration of an exposure system of a comparative example. The comparative example of the present disclosure is an example recognized by the applicant as known only by the applicant, and is not a publicly known example admitted by the applicant. The exposure system includes a laser device 1 and an exposure apparatus 200. The exposure apparatus 200 includes a processor (not shown). The processor included in the exposure apparatus 200 is configured to transmit various signals such as a gate signal GS, a voltage designation signal VS, and a light emission trigger signal TS (see FIG. 4) to the controller 30 which is a processor included in the laser device 1. Hereinafter, a signal from the processor included in the exposure apparatus 200 may be simply referred to as a signal from the exposure apparatus 200. The exposure apparatus 200 is an example of the external apparatus in the present disclosure.

### 1.2 Laser Device 1

### 1.2.1 Configuration

The laser device 1 includes the controller 30, a laser oscillator 110, and an energy monitor 160. The laser oscillator 110 that performs laser oscillation includes a chamber 10, a charger 12, a pulse power module 13, a line narrowing module 14, and an output coupling mirror 15. The line narrowing module 14 and the output coupling mirror 15 configure an optical resonator. The chamber 10 includes windows 10a, 10b and a pair of electrodes 11a, 11b. The chamber 10 is arranged such that the windows 10a, 10b are located on the optical path of the optical resonator.

The line narrowing module 14 includes a prism 14a and a grating 14b. The prism 14a is arranged on the optical path of light output from the window 10a. The grating 14b is arranged on the optical path of the light having transmitted through the prism 14a. The output coupling mirror 15 is configured of a partial reflection mirror, and is arranged on the optical path of light output from the window 10b.

The chamber 10 is filled with a laser gas containing, for example, an argon gas or a krypton gas as a rare gas, a fluorine gas as a halogen gas, a neon gas as a buffer gas, and the like. Alternatively, a laser gas containing a fluorine gas and a buffer gas may be enclosed.

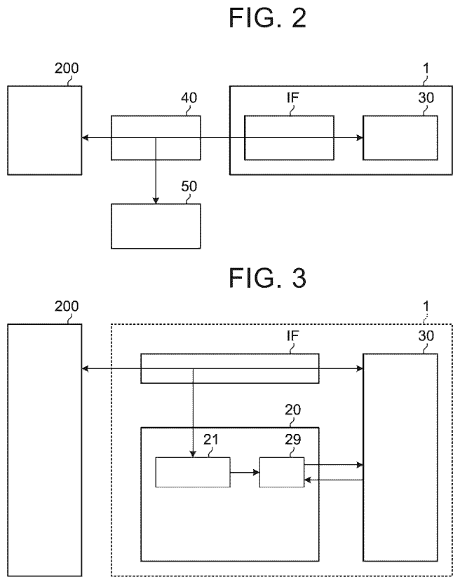

Upon receiving various signals from the exposure apparatus 200 via an interface IF (see FIG. 2), the controller 30 transmits a reception check signal to the exposure apparatus 200 via the interface IF, and controls the laser oscillator 110 in accordance with the various signals. The exposure apparatus 200 transmits various signals to the controller 30 while checking that the reception check signal has been received.

The energy monitor 160 includes a beam splitter 61 and an optical sensor 62. The beam splitter 61 is arranged on the optical path of pulse laser light LB output from the output coupling mirror 15. The beam splitter 61 transmits a part of the pulse laser light LB toward the exposure apparatus 200 at high transmittance, and reflects the other part thereof toward the optical sensor 62. The optical sensor 62 is, for example, a photodiode having sensitivity to ultraviolet light such as the pulse laser light LB. The optical sensor 62 measures the pulse energy of the pulse laser light LB reflected by the beam splitter 61, and transmits the measurement result to the controller 30.

### 1.2.2 Operation

The gate signal GS is a signal for instructing starting of burst oscillation for continuously outputting the pulse laser light LB at a predetermined repetition frequency. When the controller 30 receives the voltage designation signal VS in a state in which the gate signal GS is on, the controller 30 transmits a charge voltage command value to the charger 12. Upon receiving the light emission trigger signal TS from the exposure apparatus 200, the controller 30 transmits a trigger signal to the pulse power module 13.

Upon receiving the trigger signal from the controller 30, the pulse power module 13 generates a pulse high voltage from the electric energy held in the charger 12 and applies the high voltage between the electrodes 11a, 11b.

When the high voltage is applied between the electrodes 11a, 11b, discharge occurs between the electrodes 11a, 11b according to the voltage specified by the voltage designation signal VS and the timing corresponding to the light emission trigger signal TS. The laser medium in the chamber 10 is excited by the energy of the discharge and shifts to a high energy level. When the excited laser medium then shifts to a low energy level, light having a wavelength corresponding to the difference between the energy levels is emitted.

The light generated in the discharge space between the electrodes 11a, 11b is output to the outside of the chamber 10 through the windows 10a, 10b. The beam width of the light output through the window 10a is expanded by the prism 14a, and then the light is incident on the grating 14b. The light incident on the grating 14b is reflected by a plurality of grooves of the grating 14b and is diffracted in a direction corresponding to the wavelength of the light. The grating 14b is arranged in the Littrow arrangement, which causes the incident angle of the light incident on the grating 14b from the prism 14a to coincide with the diffraction angle of the diffracted light having a desired wavelength. Thus, light having a wavelength close to the desired wavelength returns into the chamber 10 via the prism 14a.

The output coupling mirror 15 transmits and outputs a part of the light output from the window 10b, and reflects the other part thereof back into the chamber 10.

In this manner, the light generated in the discharge space reciprocates between the line narrowing module 14 and the output coupling mirror 15. This light is amplified each time passing through the discharge space and is line-narrowed each time being turned back in the line narrowing module 14. The light that has been amplified and line-narrowed and has undergone laser oscillation in this manner is output as the pulse laser light LB from the output coupling mirror 15 and enters the exposure apparatus 200.

The controller 30 transmits the pulse energy of the pulse laser light LB measured by the energy monitor 160 to the processor of the exposure apparatus 200. The processor of the exposure apparatus 200 transmits the voltage designation signal VS of the subsequent pulse to the controller 30 based on the pulse energy received from the controller 30.

### 1.3 Problem of Comparative Example

A communication error may occur between the laser device 1 and the exposure apparatus 200. In order to resolve the communication error and restore a normal state, it is necessary to first check a communication state between the laser device 1 and the exposure apparatus 200 and identify the origin of the problem.

FIG. 2 shows a configuration example of a system for checking the communication state between the laser device 1 and the exposure apparatus 200 in the comparative example. A signal such as a status signal and an interlock signal transmitted and received between the laser device 1 and the exposure apparatus 200 is extracted by a dedicated tool 40, and the extracted signal is received by a measurement instrument 50 such as an oscilloscope or a logger, whereby the communication state can be checked.

However, a communication line between the laser device 1 and the exposure apparatus 200 is not configured to facilitate extraction of signals to devices such as the dedicated tool 40 and the measurement instrument 50. Therefore, installation of the dedicated tool 40 and connection of the measurement instrument 50 require a specific procedure, are time-consuming, and causes a possibility of human errors. In addition, the measurement instrument 50 requires visual checking, and there is a risk of oversight or misidentification.

Embodiments described below relate to providing measures for easily and accurately checking the communication state between the laser device 1 and the exposure apparatus 200.

### 2. Laser Device 1 Including Communication Monitoring Device 20 Connected to Interface IF

### 2.1 Configuration

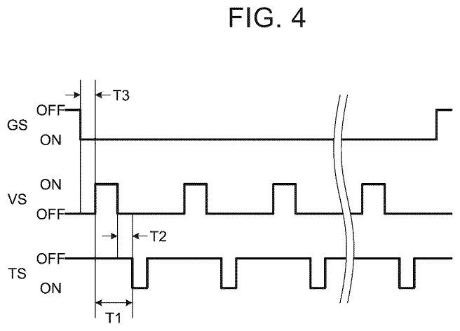

FIG. 3 shows the configuration of the laser device 1 of a first embodiment. The laser oscillator 110 and the energy monitor 160 of the first embodiment have similar configurations as those of the comparative example, and illustration thereof is omitted in FIG. 3. The laser device 1 includes the controller 30, the interface IF, and a communication monitoring device 20. The controller 30 may be similar to that of the comparative example. The interface IF is connected between the controller 30 and the exposure apparatus 200, and is configured to transmit and receive signals between the controller 30 and the exposure apparatus 200.

The communication monitoring device 20, which is a processor, includes a measurement determination circuit 21 and a memory 29. The communication monitoring device 20 is connected to the interface IF and the controller 30 via separate signal lines. The communication monitoring device 20 may be arranged in the same housing as the interface IF is.

The measurement determination circuit 21 is connected to the interface IF and is configured to detect signals transmitted and received between the controller 30 and the exposure apparatus 200 via the interface IF. The signals transmitted and received via the interface IF include a first signal and a second signal subsequent to the first signal. The measurement determination circuit 21 includes a timer and a counter for measuring time difference between the first signal and the second signal, and is configured of a dedicated circuit using, for example, a FPGA or a CPU.

The memory 29 stores the time difference between the first signal and the second signal measured by the measurement determination circuit 21.

FIG. 4 shows an example of signals detected by the measurement determination circuit 21 in the first embodiment. Each of the first signal and the second signal is a signal transmitted from one of the controller 30 and the exposure apparatus 200 to the other.

For example, the first signal may be the voltage designation signal VS transmitted from the exposure apparatus 200 to the controller 30, and the second signal may be the light emission trigger signal TS transmitted from the exposure apparatus 200 to the controller 30 subsequent to the voltage designation signal VS. Similarly to these signals, each of the first signal and the second signal may be a signal transmitted and received for each pulse of the pulse laser light LB output from the laser oscillator 110. In this case, it is desirable that the memory 29 has a capacity capable of storing data during a period corresponding to a period for exposing one semiconductor wafer to be exposed in the exposure apparatus 200. The time difference between the first signal and the second signal may be a time T1 from rising time of the voltage designation signal VS to falling time of the light emission trigger signal TS, or may be a time T2 from falling time of the voltage designation signal VS to the falling time of the light emission trigger signal TS.

Further, for example, the first signal may be the gate signal GS transmitted from the exposure apparatus 200 to the controller 30, and the second signal may be the voltage designation signal VS. In this case, the time difference between the first signal and the second signal may be a time T3 from falling time of the gate signal GS to the rising time of the voltage designation signal VS. The first signal and the second signal may be status signals other than the gate signal GS, the voltage designation signal VS, and the light emission trigger signal TS, or interlock signals.

### 2.2 Operation

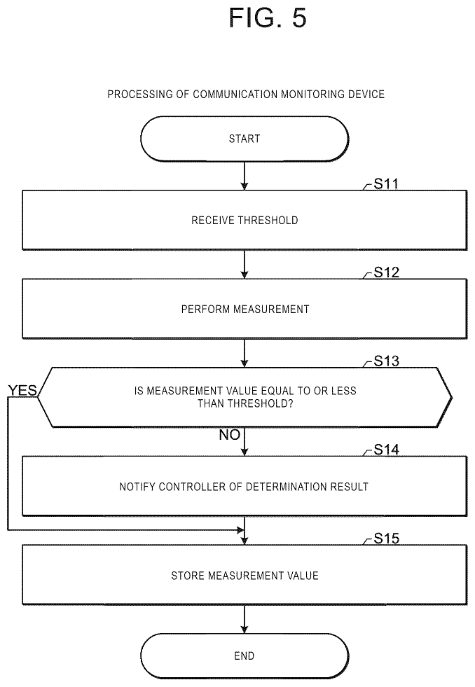

FIG. 5 is a flowchart showing processing of the communication monitoring device 20 in the first embodiment. Through the following processing, the communication monitoring device 20 measures the time difference between the first signal and the second signal, stores the measurement values, and notifies the controller 30 of the determination result when there is abnormality in the measurement values.

In S11, the communication monitoring device 20 receives a threshold of the time difference between the first signal and the second signal from the controller 30.

In S12, the communication monitoring device 20 receives the first signal and the second signal and measures the time difference between these signals.

In S13, the communication monitoring device 20 determines whether or not the measurement value of the time difference is less than the threshold. When the measurement value of the time difference is equal to or more than the threshold, there is a possibility of a communication error, and therefore, the communication monitoring device 20 advances processing to S14.

In S14, the communication monitoring device 20 notifies the controller 30 of the determination result. As a result, the controller 30 can take measures according to a situation, such as notifying the exposure apparatus 200, transitioning to a warning state, or stopping laser oscillation. The communication monitoring device 20 thus notifying the controller 30 of the determination result corresponds to the communication monitoring device notifying the controller of the information regarding time in the present disclosure.

When the measurement value of the time difference is less than the threshold in S13, or after S14, the communication monitoring device 20 stores the measurement value of the time difference in the memory 29 in S15. The measurement value of the time difference may be stored as log data associated with generation time of the first signal or the second signal, or may be stored as log data associated with a pulse number of the pulse laser light LB.

After S15, the communication monitoring device 20 ends processing of the present flowchart. When a new first signal and a new second signal are generated subsequent to the first signal and the second signal measured in S12, the processing is newly started from S11 of FIG. 5 or from S12 with S11 omitted. After a plurality of measurement values are stored in the memory 29 in this manner, the controller 30 collectively acquires the plurality of measurement values or log data including the plurality of measurement values stored in the memory 29. For example, the controller 30 may collectively acquire data corresponding to a period for exposing one semiconductor wafer from the memory 29.

In FIG. 5, instead of in S15, the measurement values may be stored in the memory 29 between S12 and S13.

In FIG. 5, the case in which the communication monitoring device 20 performs determination of whether or not the measurement value is less than the threshold (S13) and notification of the determination result to the controller 30 (S14) has been described, but the present disclosure is not limited thereto, and S13 and S14 may be omitted.

When S13 and S14 are omitted, the controller 30 acquires the measurement value or the log data stored in the memory 29, and determines whether or not the measurement value is less than the threshold. The controller 30 may collectively acquire a plurality of the measurement values or log data stored in the memory 29, and determine whether or not each of the measurement values is less than the threshold. For example, the controller 30 may collectively acquire data corresponding to a period for exposing one semiconductor wafer from the memory 29.

The controller 30 acquiring the measurement value or the log data from the memory 29 of the communication monitoring device 20 corresponds to the communication monitoring device notifying the controller of the information regarding time in the present disclosure. After the controller 30 acquires the measurement value or the log data from the memory 29, new data measured by the communication monitoring device 20 is overwritten and stored in the memory 29.

### 2.3 Effect

(1) According to the first embodiment, the laser device 1 includes the laser oscillator 110, the controller 30, the interface IF, and the communication monitoring device 20. The laser oscillator 110 performs laser oscillation, the controller 30 controls the laser oscillator 110, and the interface IF is connected between the exposure apparatus 200 and the controller 30.The communication monitoring device 20 is connected to the interface IF, and detects the first signal transmitted and received via the interface IF and the second signal transmitted and received via the interface IF subsequent to the first signal, measures the time T1 from detection of the first signal to detection of the second signal, and notifies the controller 30 of information regarding the time T1. One of the controller 30 and the communication monitoring device 20 determines whether or not the time T1 is less than the threshold.

Accordingly, by measuring the time difference between the two signals transmitted and received via the interface IF, data related to the communication state between the controller 30 of the laser device 1 and the exposure apparatus 200 can be acquired, and the location where a problem related to the communication state is occurring can be identified. Further, manual connection work of signal measurement instruments and visual checking work at the site can be reduced, and human errors can be reduced.

(2) According to the first embodiment, the communication monitoring device 20 determines whether or not the time T1 is less than the threshold, and when it is determined that the time T1 is less than the threshold, the communication monitoring device 20 stores the time T1, and collectively notifies the controller 30 of the result after storing the result of measuring the time T1 a plurality of times.

Accordingly, since the controller 30 does not need to perform determination for the time T1 each time, the load on the controller 30 can be reduced. Further, since the measurement result is collectively notified to the controller 30, it is possible to suppress the load of communication between the communication monitoring device 20 and the controller 30 even when measurement is performed at a high frequency, for example, for each pulse of the pulse laser light LB. Further, since new data can be overwritten in the memory 29 after notifying the controller 30, the necessity of increasing the capacity of the memory 29 included in the communication monitoring device 20 can be reduced.

(3) According to the first embodiment, the communication monitoring device 20 determines whether or not the time T1 is less than the threshold, and the communication monitoring device 20 notifies the controller 30 of the determination result when it is determined that the time T1 is equal to or more than the threshold.

Accordingly, since the controller 30 does not need to perform determination for the time T1 each time, the load on the controller 30 can be reduced. Further, determination of the communication state can be performed before the data including the measurement value is collectively transmitted from the communication monitoring device 20 to the controller 30.

(4) According to the first embodiment, each of the first signal and the second signal is a signal transmitted from one of the exposure apparatus 200 and the controller 30 to the other.

Accordingly, by directly monitoring the communication between the exposure apparatus 200 and the controller 30, the necessity of providing a circuit that separately generates a signal can be reduced.

(5) According to the first embodiment, each of the first signal and the second signal may be a signal transmitted and received for each pulse of the pulse laser light LB output from the laser oscillator 110.

Accordingly, since the time difference is measured by acquiring a pair of signals transmitted and received for each pulse of the pulse laser light LB, it is expected that the time difference is substantially constant when the communication is normal, and it is possible to detect abnormality of the communication when the time difference is equal to or more than the threshold. Further, when the time difference of the signals corresponding to each of all the pulses is measured, it is possible to obtain detailed data.

(6) According to the first embodiment, one of the first signal and the second signal is the voltage designation signal VS transmitted from the exposure apparatus 200 to the controller 30, and the controller 30 controls the laser oscillator 110 so as to cause laser oscillation by discharge with the voltage designated by the voltage designation signal VS.

Accordingly, by monitoring the voltage designation signal VS, it is possible to detect a defect in the signal path specific to the discharge-excitation-type laser device 1 controlled by the voltage.

(7) According to the first embodiment, one of the first signal and the second signal is the light emission trigger signal TS transmitted from the exposure apparatus 200 to the controller 30, and the controller 30 controls the laser oscillator 110 so as to cause laser oscillation by discharge at a timing corresponding to the light emission trigger signal TS.

Accordingly, by monitoring the light emission trigger signal TS, it is possible to detect a defect in the signal path specific to the laser device 1 that performs pulse oscillation.

In other respects, the first embodiment is similar to the comparative example.

### 3. Laser Device 1 Including Communication Monitoring Device 20 that Performs Polling

### 3.1 Configuration

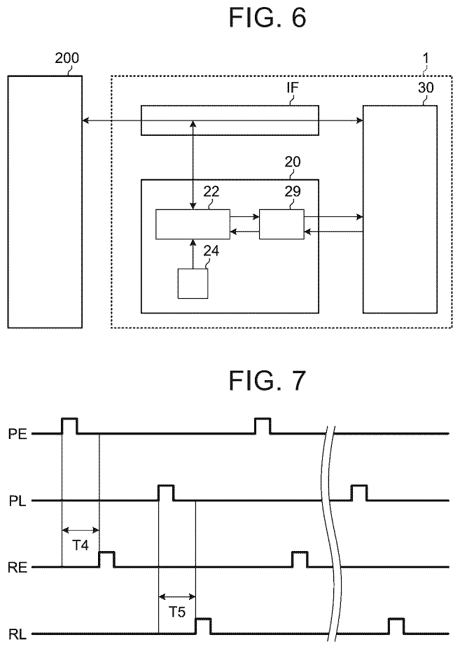

FIG. 6 shows the configuration of the laser device 1 of a second embodiment. In the second embodiment, the communication monitoring device 20, which is a processor, includes a polling circuit 22, a clock 24, and the memory 29.

The polling circuit 22 is connected to the interface IF and is configured to transmit a polling signal PE or PL (see FIG. 7) to one of the controller 30 and the exposure apparatus 200 for inquiring about a status signal and detect a response signal RE or RL to the polling signal PE or PL. The polling signal PE or PL is an example of the first signal in the present disclosure, and the response signal RE or RL is an example of the second signal in the present disclosure, and both thereof are transmitted and received via the interface IF. The polling circuit 22 includes a timer and a counter for measuring the time from transmission of the polling signal PE or PL to detection of the response signal RE or RL. The polling circuit 22 is configured of a dedicated circuit using, for example, a FPGA or a CPU.

The clock 24 generates a clock signal of a predetermined cycle in order to manage a time interval between transmission of the previous polling signal PE or PL and transmission of the subsequent polling signal PE or PL. The polling signal PE or PL may be transmitted at a frequency lower than the repetition frequency of the pulse laser light LB output from the laser oscillator 110. When the frequency of the polling signal PE or PL is decreased, data over a long period of time can be stored in the memory 29, and when the frequency is increased, detailed data can be acquired.

The memory 29 stores the time difference, measured by the polling circuit 22, between the polling signal PE or PL and the response signal RE or RL.

FIG. 7 shows an example of signals transmitted and received by the polling circuit 22 in the second embodiment. The polling circuit 22 may transmit the polling signal PE or PL to each of the exposure apparatus 200 and the controller 30, and receives the response signal RE or RL.

The polling circuit 22 may measure a time T4 from transmission of the polling signal PE to the exposure apparatus 200 to reception of the response signal RE, or may measure a time T5 from transmission of the polling signal PL to the controller 30 to reception of the response signal RL.

### 3.2 Operation

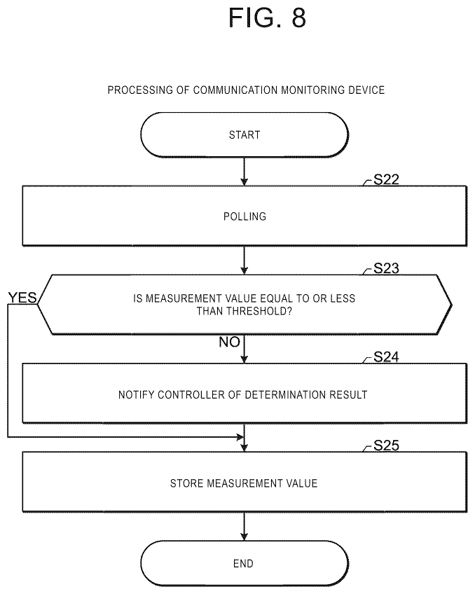

FIG. 8 is a flowchart showing processing of the communication monitoring device 20 in the second embodiment. Through the following processing, the communication monitoring device 20 measures the time difference between the first signal and the second signal, stores the measurement value, and notifies the controller 30 of the determination result when there is abnormality in the measurement value.

In S22, the communication monitoring device 20 transmits the polling signal PE or PL to one of the exposure apparatus 200 and the controller 30, and measures the time difference until the response signal RE or RL is received.

In S23, the communication monitoring device 20 determines whether or not the measurement value of the time difference is less than a threshold. When the measurement value of the time difference is equal to or more than the threshold, there is a possibility of a communication error, and therefore, the communication monitoring device 20 advances processing to S24.

In S24, the communication monitoring device 20 notifies the controller 30 of the determination result. As a result, the controller 30 can take measures according to a situation, such as notifying the exposure apparatus 200, transitioning to a warning state, or stopping laser oscillation. The communication monitoring device 20 thus notifying the controller 30 of the determination result corresponds to the communication monitoring device notifying the controller of the information regarding time in the present disclosure.

When the measurement value of the time difference is less than the threshold in S23, or after S24, the communication monitoring device 20 stores the measurement value of the time difference in the memory 29 in S25. The measurement value of the time difference may be stored as log data associated with generation time of the polling signal PE or PL or of the response signal RE or RL, or may be stored as log data associated with a pulse number of the pulse laser light LB.

After S25, the communication monitoring device 20 ends processing of the present flowchart. When a new polling signal PE or PL is generated after the polling signal PE or PL transmitted in S22, the processing is newly started from S22 in FIG. 8. After a plurality of measurement values are stored in the memory 29 in this manner, the controller 30 collectively acquires the plurality of measurement values or log data including the plurality of measurement values stored in the memory 29.

In FIG. 8, instead of in S25, the measurement values may be stored in the memory 29 between S22 and S23.

In FIG. 8, the case in which the communication monitoring device 20 performs determination of whether or not the measurement value is less than the threshold (S23) and notification of the determination result to the controller 30 (S24) has been described, but the present disclosure is not limited thereto, and S23 and S24 may be omitted.

When S23 and S24 are omitted, the controller 30 acquires the measurement value or the log data stored in the memory 29, and determines whether or not the measurement value is less than the threshold.

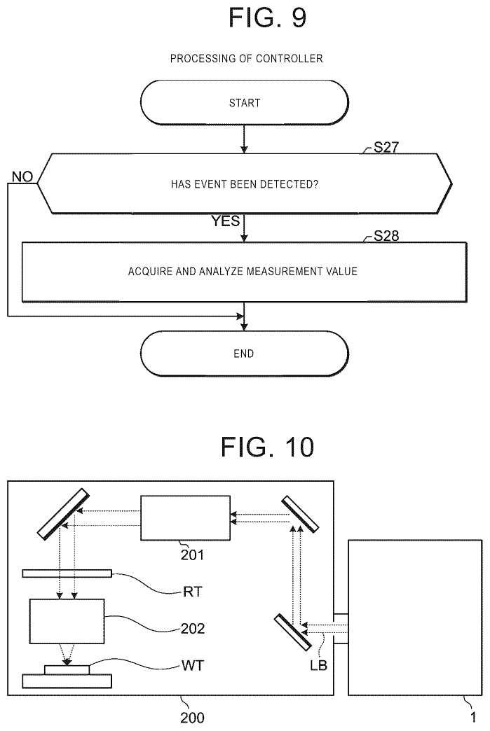

FIG. 9 is a flowchart showing processing of the controller 30 when S23 and S24 are omitted in the second embodiment. The controller 30 acquires the measurement value from the memory 29 and performs analysis through the following processing.

In S27, the controller 30 determines whether or not any event has been detected. The event may be related to communication abnormality with the exposure apparatus 200, or may be another event. The event may be an error or a warning. When the event is detected, the controller 30 advances processing to S28.

In S28, the controller 30 receives the measurement value or the log data from the memory 29 of the communication monitoring device 20 and performs analysis. The analysis includes determining whether or not the measurement value is less than the threshold, identifying the origin of the problem when there is a communication error, and identifying from which time point the problem occurred, or any of these. The measurement values or the log data acquired from the memory 29 may be data corresponding to a period longer than a period for exposing one semiconductor wafer.

If no error is detected in S27, or after S28, the controller 30 ends processing of the present flowchart.

### 3.3 Effect

(8) According to the second embodiment, the first signal is the polling signal PE or PL transmitted from the communication monitoring device 20 to one of the exposure apparatus 200 and the controller 30, and the second signal is the response signal RE or RL to the polling signal PE or PL.

Accordingly, by transmitting the polling signal PE to the exposure apparatus 200 and receiving the response signal RE, it is possible to detect a defect in a signal path between the interface IF and the exposure apparatus 200. By transmitting the polling signal PL to the controller 30 and receiving the response signal RL, it is possible to detect a defect in a signal path between the interface IF and the controller 30.

(9) According to the second embodiment, the polling signal PE or PL is a signal transmitted and received at a frequency lower than the repetition frequency of the pulse laser light LB output from the laser oscillator 110.

Accordingly, by setting the frequency of the polling signal PE or PL to a frequency lower than the repetition frequency of the pulse laser light LB, it is possible to suppress the data amount even when data is acquired over a long period of time.

(10) According to the second embodiment, the communication monitoring device 20 stores the result of measuring the time T4 or T5 a plurality of times, and the controller 30 receives the result from the communication monitoring device 20 when an event related to communication abnormality is detected, and determines whether or not the time T4 or T5 is less than the threshold.

Accordingly, the controller 30 collectively receives the measurement result when the event related to communication abnormality is detected, thereby reducing the load of communication between the controller 30 and the communication monitoring device 20. Further, the controller 30 performs determination, so that the load on the communication monitoring device 20 can be reduced.

In other respects, the second embodiment is similar to the first embodiment.

### 4. Others

### 4.1 Processor

The processor of the exposure apparatus 200, and the controller and the communication monitoring device 20, which are processors, may each be physically configured as hardware to execute various processes included in the present disclosure. For example, the processor may be a computer including a memory that stores a control program defining the various processes and a processing device that executes the control program. The control program may be stored in one memory, or may be stored separately in a plurality of memories at physically separate locations, and the various processes may be defined by the control program as an aggregation thereof. The processing device may be a general-purpose processing device such as a CPU or a special-purpose processing device such as a GPU.

Alternatively, the processor may be programmed as software to execute the various processes included in the present disclosure. For example, the processor may be implemented in a dedicated device such as an ASIC or a programmable device such as an FPGA.

The various processes included in the present disclosure may be executed by one computer, one dedicated device, or one programmable device, or may be executed by cooperation of a plurality of computers, a plurality of dedicated devices, or a plurality of programmable devices at physically separate locations. The various processes may be executed by a combination including at least any two of: one or more computers, one or more dedicated devices, and one or more programmable devices.

### 4.2 Electronic Device Manufacturing Method

FIG. 10 schematically shows the configuration of the exposure apparatus 200. The exposure apparatus 200 includes an illumination optical system 201 and a projection optical system 202. The illumination optical system 201 illuminates a reticle pattern of a reticle (not shown) arranged on a reticle stage RT with the pulse laser light LB incident from the laser device 1. The projection optical system 202 causes the pulse laser light LB transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 200 synchronously translates the reticle stage RT and the workpiece table WT to expose the workpiece to the pulse laser light LB reflecting the reticle pattern. After the reticle pattern is transferred onto the semiconductor wafer by the exposure process described above, an electronic device can be manufactured through a plurality of processes.

### 4.3 Supplement

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of any thereof and any other than A, B, and C.

What is claimed is:

1. A laser device comprising:
a laser oscillator configured to perform laser oscillation;
a controller configured to control the laser oscillator;
an interface connected between an external apparatus and the controller; and
a communication monitoring device connected to the interface, the communication monitoring device being configured to:
detect a first signal transmitted and received via the interface and a second signal transmitted and received via the interface subsequent to the first signal,
measure a time from detection of the first signal to detection of the second signal, and
notify the controller of information regarding the time,
one of the controller and the communication monitoring device determining whether or not the time is less than a threshold.

2. The laser device according to claim 1,
wherein the communication monitoring device determines whether or not the time is less than the threshold, and when the time is determined to be less than the threshold, the communication monitoring device stores the time, and after storing a result of measuring the time a plurality of times, collectively notifies the controller of the result.

3. The laser device according to claim 2,
wherein the communication monitoring device determines whether or not the time is less than the threshold, and the communication monitoring device notifies the controller of a determination result when the time is determined to be equal to or more than the threshold.

4. The laser device according to claim 1,
wherein each of the first signal and the second signal is a signal transmitted from one of the external apparatus and the controller to the other.

5. The laser device according to claim 4,
wherein each of the first signal and the second signal is a signal transmitted and received for each pulse of pulse laser light output from the laser oscillator.

6. The laser device according to claim 4,
wherein one of the first signal and the second signal is a voltage designation signal transmitted from the external apparatus to the controller, and
the controller controls the laser oscillator so as to cause laser oscillation by discharge with a voltage designated by the voltage designation signal.

7. The laser device according to claim 4,
wherein one of the first signal and the second signal is a light emission trigger signal transmitted from the external apparatus to the controller, and
the controller controls the laser oscillator so as to cause laser oscillation by discharge at a timing corresponding to the light emission trigger signal.

8. The laser device according to claim 1,
wherein the first signal is a polling signal transmitted from the communication monitoring device to one of the external apparatus and the controller, and
the second signal is a response signal to the polling signal.

9. The laser device according to claim 8,
wherein the polling signal is a signal transmitted and received at a frequency lower than a repetition frequency of pulse laser light output from the laser oscillator.

10. The laser device according to claim 8,
wherein the communication monitoring device stores a result of measuring the time a plurality of times, and
the controller receives the result from the communication monitoring device when an event related to communication abnormality is detected, and determines whether or not the time is less than the threshold.

11. An electronic device manufacturing method, comprising:
generating pulse laser light using a laser device;
outputting the pulse laser light to an exposure apparatus; and
exposing a photosensitive substrate to the pulse laser light in the exposure apparatus to manufacture an electronic device,
the laser device including:
a laser oscillator configured to perform laser oscillation;
a controller configured to control the laser oscillator;
an interface connected between the exposure apparatus and the controller; and
a communication monitoring device connected to the interface, the communication monitoring device being configured to:
detect a first signal transmitted and received via the interface and a second signal transmitted and received via the interface subsequent to the first signal,
measure a time from detection of the first signal to detection of the second signal, and
notify the controller of information regarding the time,
one of the controller and the communication monitoring device determining whether or not the time is less than a threshold.

12. The electronic device manufacturing method according to claim 11,
wherein the communication monitoring device determines whether or not the time is less than the threshold, and when the time is determined to be less than the threshold, the communication monitoring device stores the time, and after storing a result of measuring the time a plurality of times, collectively notifies the controller of the result.

13. The electronic device manufacturing method according to claim 12,
wherein the communication monitoring device determines whether or not the time is less than the threshold, and the communication monitoring device notifies the controller of a determination result when the time is determined to be equal to or more than the threshold.

14. The electronic device manufacturing method according to claim 11,
wherein each of the first signal and the second signal is a signal transmitted from one of the exposure apparatus and the controller to the other.

15. The electronic device manufacturing method according to claim 14,
wherein each of the first signal and the second signal is a signal transmitted and received for each pulse of the pulse laser light.

16. The electronic device manufacturing method according to claim 14,
wherein one of the first signal and the second signal is a voltage designation signal transmitted from the exposure apparatus to the controller, and
the controller controls the laser oscillator so as to cause laser oscillation by discharge with a voltage designated by the voltage designation signal.

17. The electronic device manufacturing method according to claim 14,
wherein one of the first signal and the second signal is a light emission trigger signal transmitted from the exposure apparatus to the controller, and
the controller controls the laser oscillator so as to cause laser oscillation by discharge at a timing corresponding to the light emission trigger signal.

18. The electronic device manufacturing method according to claim 11,
wherein the first signal is a polling signal transmitted from the communication monitoring device to one of the exposure apparatus and the controller, and
the second signal is a response signal to the polling signal.

19. The electronic device manufacturing method according to claim 18,
wherein the polling signal is a signal transmitted and received at a frequency lower than a repetition frequency of the pulse laser light.

20. The electronic device manufacturing method according to claim 18,
wherein the communication monitoring device stores a result of measuring the time a plurality of times, and
the controller receives the result from the communication monitoring device when an event related to communication abnormality is detected, and determines whether or not the time is less than the threshold.
